(19) United States
(12) Patent Application Publication
(10) Pub. No.: US 2023/0282472 A1
(43) Pub. Date: Sep. 7, 2023

(54) WAFER AND METHOD OF PROCESSING WAFER

(71) Applicant: GlobalWafers Co., Ltd., Hsinchu (TW)

(72) Inventors: Wen-Huai Yu, Hsinchu (TW); Shih-Che Hung, Hsinchu (TW); Hung-Chang Lo, Hsinchu (TW); Chun-I Fan, Hsinchu (TW); Chia-Chi Tsai, Hsinchu (TW); Wen-Ching Hsu, Hsinchu (TW)

(73) Assignee: GlobalWafers Co., Ltd., Hsinchu (TW)

(21) Appl. No.: 18/177,130

(22) Filed: Mar. 2, 2023

Related U.S. Application Data
(60) Provisional application No. 63/315,953, filed on Mar. 2, 2022.

(51) Int. Cl. H01L 21/02

(52) U.S. Cl. CPC H01L 21/02019

(57) ABSTRACT

A wafer and a wafer processing method are included. The wafer processing method includes the following steps. A wafer is provided having a first surface and a second surface opposite to the first surface. A fixture pattern is pasted on the first surface to cover a first portion of the first surface of the wafer, and a second portion of the first surface is exposed by the fixture pattern. A first etching step is performed on the second portion of the first surface to form a first etching pattern on the first surface of the wafer. The fixture pattern is removed from the first surface, and the second surface of the wafer is ground.

### CROSS-REFERENCE TO RELATED APPLICATION

This application claims the priority benefit of U.S. provisional application Ser. No. 63/315,953, filed on Mar. 2, 2022. The entirety of the above-mentioned patent application is hereby incorporated by reference herein and made a part of the specification.

### BACKGROUND

### Technical Field

The disclosure relates to a wafer, and in particular, to a wafer and a wafer processing method.

### Description of Related Art

At present, silicon wafers have been widely used in the semiconductor industry. Many electronic devices contain silicon chips produced using the silicon wafers as materials. In order to improve the performance of the chips, many manufacturers are also trying to produce the chips with different materials such as silicon carbide wafers and gallium nitride wafers.

As far as the existing technology is concerned, in the case of a conventional large-sized or an insufficiently rigid wafer, an ultra-thin wafer, or when the wafer itself has crystal internal stress, the wafer is easily deformed by stress. In the way, the quality of the wafer formed by subsequent dicing will be affected. Therefore, it remains a problem to be solved on how to reduce the gravity or the external force or adjust the influence of internal stress on the geometric shape of the wafer.

### SUMMARY

The disclosure provides a wafer and a wafer processing method, which may reduce the gravity or the external force or adjust the influence of the internal stress on the geometric shape of the wafer.

Some embodiments of the disclosure provide a wafer processing method, which include the following steps. A wafer is provided having a first surface and a second surface opposite to the first surface. A fixture pattern is pasted on the first surface to cover a first portion of the first surface, and a second portion of the first surface is exposed by the fixture pattern. A first etching step is performed on the second portion of the first surface to form a first etching pattern on the first surface of the wafer.

In an embodiment of the disclosure, after the second surface of the wafer is ground, a convex pattern is formed on the second surface, and the position of the convex pattern corresponds to the position of the first etching pattern of the first surface.

In an embodiment of the disclosure, the convex pattern is one or more circles, ellipses, arcs, straight lines, rings, spirals, semicircles, polygons, irregular shapes, or a combination thereof protruding outwards from the second surface.

In an embodiment of the disclosure, the first etching pattern is one or more circles, ellipses, arcs, straight lines, rings, spirals, semicircles, polygons, irregular shapes, or a combination thereof recessed inwards from the first surface.

In an embodiment of the disclosure, the first etching pattern is a symmetrically disposed pattern.

In an embodiment of the disclosure, the first etching pattern is an asymmetrically disposed pattern.

In an embodiment of the disclosure, the ratio of the overall thickness of the wafer to the etching depth of the first etching pattern is 1:0.01 to 1:0.1.

In an embodiment of the disclosure, the etching depth of the first etching pattern is 1 μm to 1000 μm.

In an embodiment of the disclosure, after the fixture pattern is removed from the first surface and before the second surface of the wafer is ground, the method further includes the following steps. A second fixture pattern is pasted on the first surface to cover a third portion of the first surface, and a fourth portion of the first surface is exposed by the fixture pattern. A second etching step is performed on the fourth portion of the first surface to form a second etching pattern on the first surface of the wafer. The second fixture pattern is removed, and the second surface of the wafer is ground.

In an embodiment of the disclosure, the etching depth of the second etching pattern is different from the etching depth of the first etching pattern.

In an embodiment of the disclosure, the etching depth of the second etching pattern is the same as the etching depth of the first etching pattern.

In an embodiment of the disclosure, before the fixture pattern is pasted on the first surface, the stress concentration place of the wafer is confirmed using an optical inspection machine. The stress concentration place of the wafer is exposed by the fixture pattern, and the first etching step includes etching the stress concentration place of the wafer.

In an embodiment of the disclosure, the fixture pattern is pasted on the first surface by using a wax or an adhesive tape.

Some embodiments of the disclosure provide a wafer having a first surface and a second surface opposite to the first surface. The first surface of the wafer has a first etching pattern recessed inwards from the first surface.

In an embodiment of the disclosure, the second surface has a convex pattern protruding outwards from the second surface, and the position of the convex pattern corresponds to the position of the first etching pattern of the first surface.

In an embodiment of the disclosure, the first etching pattern includes one or more circles, ellipses, arcs, straight lines, rings, spirals, semicircles, polygons, irregular shapes, or a combination thereof.

In an embodiment of the disclosure, the ratio of the overall thickness of the wafer to the etching depth of the first etching pattern is 1:0.01 to 1:0.1.

In an embodiment of the disclosure, the etching depth of the first etching pattern is 1 μm to 1000 μm.

In an embodiment of the disclosure, the area of the first etching pattern occupies 25% to 85% of the total area of the first surface.

Some embodiments of the disclosure provide a wafer having a first surface and a second surface opposite to the first surface. The first surface of the wafer has a convex pattern protruding outwards from the first surface.

In an embodiment of the disclosure, the second surface has an inward concave pattern recessed inwards from the second surface, and the position of the inward concave pattern corresponds to the position of the convex pattern of the first surface.

Based on the above, since the surface of the wafer prepared in the embodiment of the disclosure has at least one etching pattern (or inward concave pattern) recessed inwards, or one convex pattern protruding outwards, after the wafer is ground/polished, it may reduce the gravity or the external force or to adjust the influence of the internal stress on the geometric shape of the wafer, so that the effect of reducing the geometric warpage such as bow and/or warp in the appearance of the wafer may be achieved.

### BRIEF DESCRIPTION OF THE DRAWINGS

FIG. 1A to FIG. 1E are schematic flow diagrams of a wafer processing method according to an embodiment of the disclosure.

FIG. 2A to FIG. 2C are schematic flow diagrams of a wafer processing method according to another embodiment of the disclosure.

FIG. 3 is a schematic top view diagram of a fixture pattern according to various embodiments of the disclosure.

### DESCRIPTION OF THE EMBODIMENTS

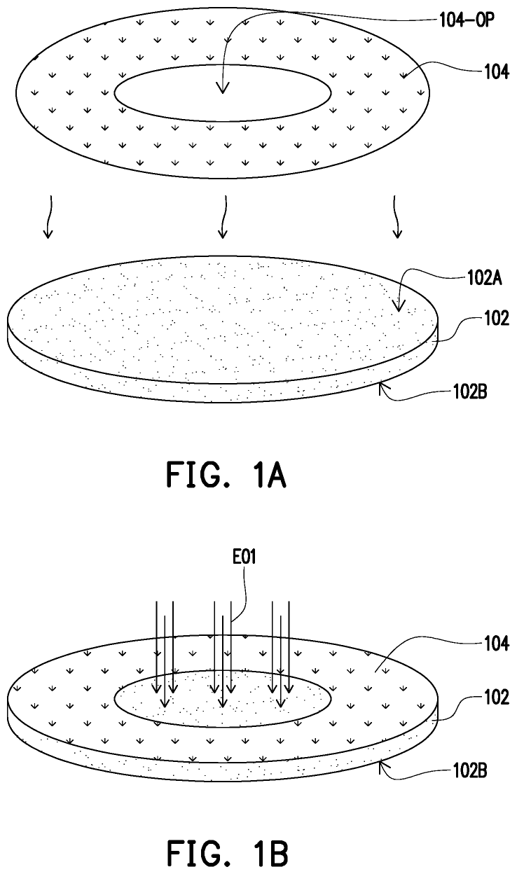

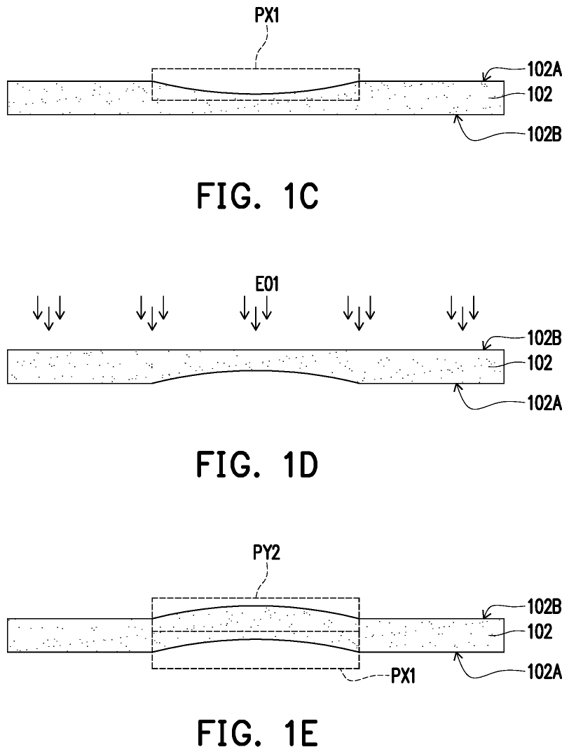

FIG. 1A to FIG. 1E are schematic flow diagrams of a wafer processing method according to an embodiment of the disclosure. Referring to FIG. 1A, in an embodiment of the disclosure, a wafer 102 and a fixture pattern 104 are provided. As shown in FIG. 1A, the wafer 102 has a first surface 102A and a second surface 102B opposite to the first surface 102A. The wafer 102 is, for example, a silicon wafer, a silicon carbide wafer, a gallium nitride wafer, or a related substrate that may require an optimized geometry or a resistance to the gravity or the deformation caused by an external force. In an embodiment of the disclosure, the wafer 102 is a silicon carbide wafer. In some embodiments, the fixture pattern 104 is, for example, a silicon fixture pattern made of silicon. In other embodiments, fixture patterns made of other materials may also be used.

In the embodiment, the fixture pattern 104 includes a circular opening 104-OP, but the disclosure is not limited thereto. In some other embodiments, the fixture pattern 104 may also include openings 104-OP of other shapes according to actual needs. In an embodiment, if the wafer 102 is a 6-inch wafer, the fixture pattern 104 is a fixture pattern 104 in which a 4-inch circular opening is dug in the center of the 6-inch silicon wafer. In the embodiment of the disclosure, the fixture pattern 104 is used for pasting on the first surface 102A of the wafer 102. In some embodiments, before the fixture pattern 104 is pasted on the first surface 102A, the stress concentration place of the wafer 102 is confirmed using an optical inspection machine. The opening 104-OP of the fixture pattern 104, for example, exposes the stress concentration place of the wafer 102. In other words, the design of the opening 104-OP in the fixture pattern 104 may be properly adjusted according to the stress concentration place of the wafer 102.

Next, referring to FIG. 1B, the fixture pattern 104 is pasted on the first surface 102A of the wafer 102 to cover a first portion of the first surface 102A, and a second portion of the first surface 102A is exposed by the fixture pattern 104. For example, the fixture pattern 104 is pasted on the first surface 102A of the wafer 102 by using a wax or an adhesive tape for temporary bonding. As shown in FIG. 1B and FIG. 1C, in some embodiments, a first etching step E01 is performed on the second portion exposed on the first surface 102A of the wafer 102, so that a first etching pattern PX1 is formed on the first surface 102A of the wafer 102. The first etching step E01 includes, for example, an inductive coupled plasma etching step, and the first etching step E01 includes etching the stress concentration place of the wafer 102.

As shown in FIG. 1C, after the first etching step E01 is performed, the first etching pattern PX1 recessed inwards from the first surface 102A will be formed on the first surface 102A of the wafer 102. In some embodiments, the ratio of the overall thickness of the wafer 102 to the etching depth of the first etching pattern PX1 is 1:0.01 to 1:0.1. In some embodiments, the ratio of the overall thickness of the wafer 102 to the etching depth of the first etching pattern PX1 is 1:0.02 to 1:0.08. In some embodiments, the ratio of the overall thickness of the wafer 102 to the etching depth of the first etching pattern PX1 is 1:0.01 to 1:0.03. In some embodiments, the ratio of the overall thickness of the wafer 102 to the etching depth of the first etching pattern PX1 is 1:0.031 to 1:0.06. In some embodiments, the ratio of the overall thickness of the wafer 102 to the etching depth of the first etching pattern PX1 is 1:0.061 to 1:0.09. In some embodiments, the ratio of the overall thickness of the wafer 102 to the etching depth of the first etching pattern PX1 is 1:0.061 to 1:0.1.

In some embodiments of the disclosure, the etching depth of the first etching pattern PX1 is 1 μm to 1000 μm. In some embodiments, the etching depth of the first etching pattern PX1 is 1 μm to 200 μm. In some embodiments, the etching depth of the first etching pattern PX1 is 1 μm to 50 μm. In some embodiments, the etching depth of the first etching pattern PX1 is 3 μm to 30 μm. In some embodiments, the etching depth of the first etching pattern PX1 is 6 μm to 20 μm. In addition, in some embodiments, the area of the first etching pattern PX1 occupies 25% to 85% of the total area of the first surface 102A. In some embodiments, the area of the first etching pattern PX1 occupies 25% to 50% of the total area of the first surface 102A. In some embodiments, the area of the first etching pattern PX1 occupies 51% to 70% of the total area of the first surface 102A. In the embodiment of the disclosure, when the etching depth and the area of the etching pattern on the surface of the wafer 102 meet the above range, it is possible to effectively reduce the gravity or the external force or adjust the influence of the internal stress on the geometric shape of the wafer.

Next, referring to FIG. 1D, after the fixture pattern 104 is removed from the first surface 102A, the wafer 102 is turned over and a grinding step G01 is performed on the second surface 102B (not shown). Referring to FIG. 1E, after the grinding is completed, a convex pattern PY2 is formed on the second surface 102B of the wafer 102 due to the release of the suction force. For example, the position of the convex pattern PY2 corresponds to the position of the first etching pattern PX1 of the first surface 102A. In some embodiments, if the first etching pattern PX1 includes a circular pattern, the convex pattern PY2 should also include a corresponding circular pattern. In some embodiments, the protrusion height of the convex pattern PY2 and the etching depth of the first etching pattern PX1 may be the same or different. In some embodiments, the first surface 102A of the wafer 102 after the completion of the transfer printing may be reground according to the application requirements so as to modify the first etching pattern PX1 (concave pattern) on the backside. In addition, after the grinding process, the wafer 102 may be chemically mechanically polished on one side or both sides according to the application requirements. Accordingly, the wafer 102 of an embodiment of the disclosure may be completed.

In the embodiment of the disclosure, although an illustration of example is given where the first etching pattern PX1 (or the inward concave pattern) is formed on the first surface 102A of the wafer 102 by transfer printing using the fixture pattern 104, the disclosure is not limited thereto. In another embodiment, a convex pattern protruding outwards from the first surface 102A is formed on the first surface 102A of the wafer 102 by transfer printing using the fixture pattern 104, and an inward concave pattern inwards recessed from the second surface 102B may be formed on the second surface 102B.

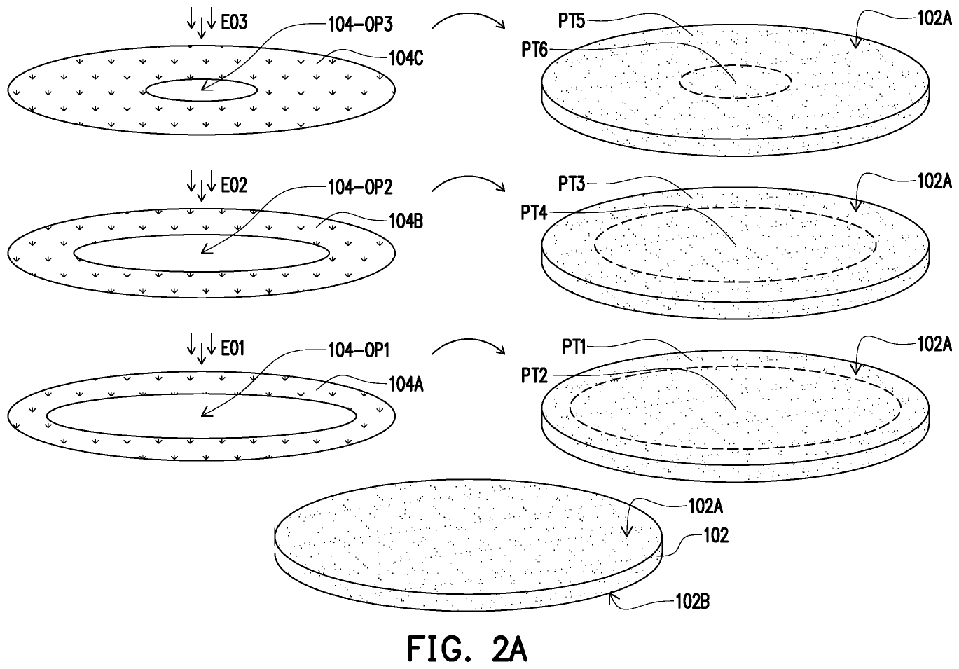

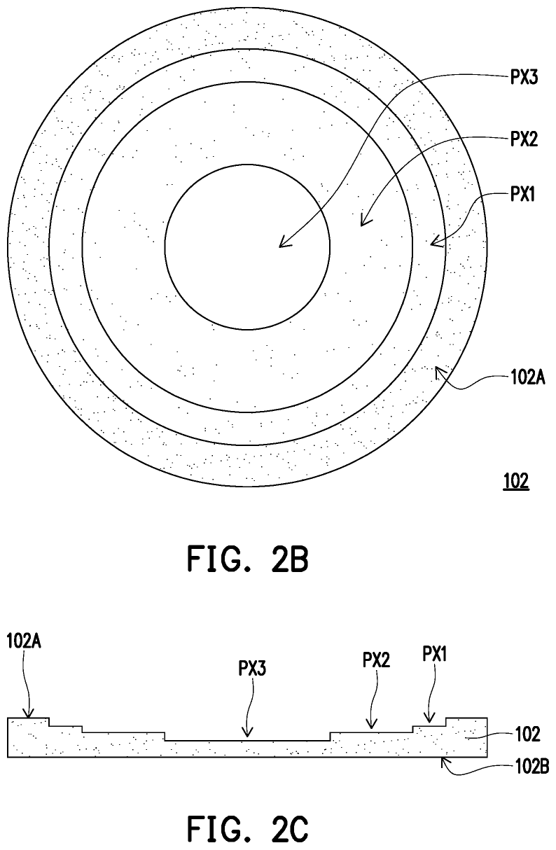

In the above-mentioned embodiment, only one fixture pattern 104 is used to form the first etching pattern PX1 (or the inward concave pattern) on the first surface 102A of the wafer 102. However, the disclosure is not limited thereto. In other embodiments, multiple fixture patterns may also be used to form multiple etching patterns on the first surface 102A of the wafer 102. Hereinafter, descriptions will be made with reference to FIG. 2A to FIG. 2C.

FIG. 2A to FIG. 2C are schematic flow diagrams of a wafer processing method according to another embodiment of the disclosure.

Referring to FIG. 2A, in some embodiments, a fixture pattern 104A is pasted on the first surface 102A of the wafer 102 to cover a first portion PT1 of the first surface 102A, and a second portion PT2 of the first surface 102A is exposed by an opening 104-OP1 of the fixture pattern 104A. Next, the first etching step E01 is performed on the second portion PT2 of the first surface 102A to form the first etching pattern PX1 on the first surface 102A of the wafer 102 as shown in FIG. 2B and FIG. 2C. Next, the fixture pattern 104A is removed from a first surface 102A of the wafer 102.

After the fixture pattern 104A is removed from the first surface 102A, a second fixture pattern 104B is pasted on the first surface 102A to cover a third portion PT3 of the first surface 102A, and a fourth portion PT4 of the first surface 102A is exposed by an opening 104-OP2 of the second fixture pattern 104B. For example, the fourth portion PT4 of the first surface 102A may overlap the aforementioned second portion PT2 of the first surface 102A. Next, a second etching step E02 is performed on the fourth portion PT4 of the first surface 102A to form a second etching pattern PX2 on the first surface 102A of the wafer 102 as shown in FIG. 2B and FIG. 2C. Next, the second fixture pattern 104B is removed from the first surface 102A of the wafer 102.

After the second fixture pattern 104B is removed from the first surface 102A, a third fixture pattern 104C is pasted on the first surface 102A to cover a fifth part PT5 of the first surface 102A, and a sixth portion PT6 of the first surface 102A is exposed by an opening 104-OP3 of the third fixture pattern 104C. For example, the sixth portion PT6 of the first surface 102A may overlap the aforementioned fourth portion PT4 of the first surface 102A. Next, a third etching step E03 is performed on the sixth portion PT6 of the first surface 102A to form a third etching pattern PX3 on the first surface 102A of the wafer 102 as shown in FIG. 2B and FIG. 2C. Finally, the third fixture pattern 104C is removed from the first surface 102A of the wafer 102. Accordingly, the multiple etching patterns may be formed on the first surface 102A of the wafer 102. After the multiple etching patterns are formed on the first surface 102A, the second surface 102B of the wafer 102 may be further ground by the steps shown in FIG. 1D and FIG. 1E, and the convex pattern PY2 is formed on the second surface 102B of the wafer 102 due to the release of the suction force, or other patterns may be formed according to designs, and the disclosure is not limited thereto.

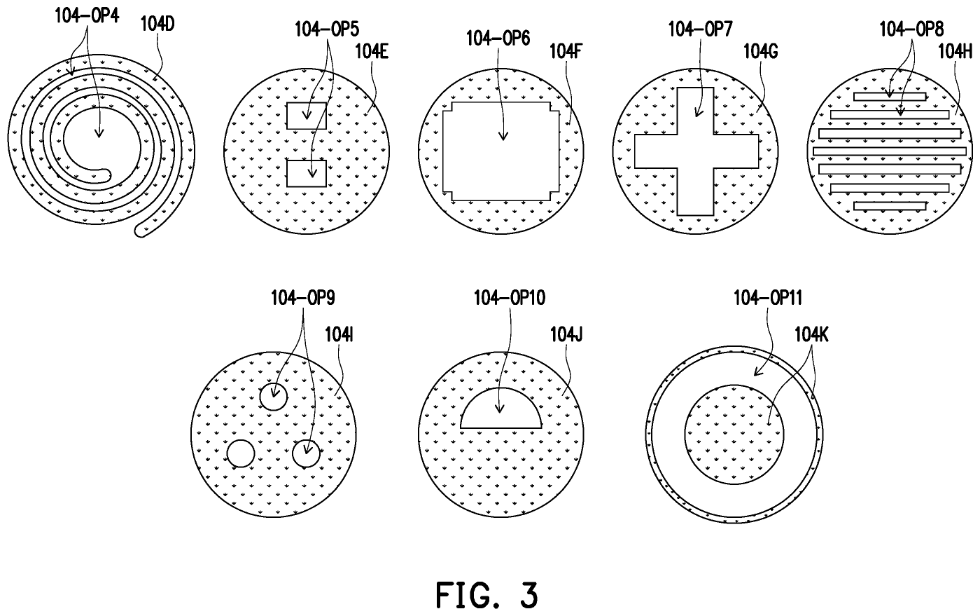

It may be known from the above-mentioned embodiments that the method of forming the etching pattern (inward concave or other patterns) on the first surface 102A is not particularly limited, and various etching patterns may be formed on the first surface 102A by using different fixture patterns to etch multiple parts of the first surface 102A. For example, an ideal etching pattern may be formed by transfer printing using the different designs of the fixture patterns as shown in FIG. 3.

FIG. 3 is a schematic top view diagram of a fixture pattern according to various embodiments of the disclosure. In the embodiment of the disclosure, the etching pattern (inward concave pattern), the convex pattern, or other patterns shown in the foregoing embodiments may be formed by transfer printing using the fixture pattern as shown in FIG. 3. For example, referring to FIG. 3, the fixture pattern 104D may have a spiral opening 104-OP4, the fixture pattern 104E may have two symmetrically disposed rectangular openings 104-OP5, the fixture pattern 104F may have a polygonal opening 104-OP6, the fixture pattern 104G may have a cross-shaped opening 104-OP7, the fixture pattern 104H may have multiple linear striped openings 104-OP8, and the fixture pattern 104I may have multiple asymmetrically disposed circular openings 104-OP9, the fixture pattern 104J may have a semicircular opening 104-OP10, and the fixture pattern 104K may have a ring-shaped opening 104-OP11.

In other words, the design of the fixture pattern is not particularly limited, and may be adjusted according to actual needs. For example, the fixture pattern may have one or more circles, ellipses, arcs, straight lines, rings, spirals, semicircles, polygons, irregular shapes, symmetry, asymmetry, a combination thereof, or other opening patterns or solid patterns of combination patterns that may be processed and formed. Accordingly, through transfer printing, the fixture patterns of different shapes may be used to form the etching pattern (inward concave pattern), convex pattern, or other patterns formed on the first surface 102A or the second surface 102B of the wafer 102 in the foregoing embodiments.

Accordingly, in some embodiments of the disclosure, the etching pattern (or inward concave pattern) may be one or more circles, ellipses, arcs, straight lines, rings, spirals, semicircles, polygons, irregular shapes, a combination thereof, or other combination patterns that may be processed and formed recessed inwards from the first surface 102A or the second surface 102B. In some embodiments of the disclosure, the convex pattern may be one or more circles, ellipses, arcs, straight lines, rings, spirals, semicircles, polygons, irregular shapes, a combination thereof, or other combination patterns that may be processed and formed protruding outwards from the first surface 102A or the second surface 102B. In addition, when multiple etching patterns or convex patterns are included, the etching patterns may each have the same etching depth or different etching depths, and the above-mentioned convex patterns may each have the same convex height or different convex heights. In addition, the etching patterns or convex patterns may be disposed continuously, discontinuously, symmetrically, asymmetrically, or in a manner of the combination thereof, on the first surface 102A or the second surface 102B.

By forming an inward concave etching pattern (or inward concave pattern) on the first surface 102A or the second surface 102B, or a convex pattern protruding outwards, after the wafer 102 is ground/polished, it is possible to reduce the gravity or the external force or adjust the influence of the internal stress on the geometric shape of the wafer, so that the effect of reducing the geometric warpage such as bow and/or warp in the appearance of the wafer may be achieved.

### EXPERIMENTAL EXAMPLES

In order to prove that the method of the disclosure may be used to improve the geometric shape of the wafer, the following experimental examples are used for illustration.

### Experimental Example 1

In Experimental Example 1, a 6-inch silicon carbide wafer was used as the basis, and after the stress concentration place of the wafer was confirmed using an optical inspection machine, a circular etching pattern as shown in FIG. 1B to FIG. 1C was formed on a carbon side of the silicon carbide wafer such as the first surface 102A. After the etching pattern was formed, the wafer was ground and polished on both sides, and the bow and the warp of the wafer were measured. In the experimental example, the previous wafer in the same wafer anchor was used as a control group where there was no etching pattern formed on the carbon side but was ground and polished on both sides. The experimental results are shown in Table 1:

TABLE 1

| | Warp | Bow |
|---|---|---|
| Control group | 258.23 | −279.99 |
| Experimental group | 222.72 | −238.51 |
| Degree of improvement | 13.8% | 14.8% |

As shown in Table 1, the wafer in the experimental group shows a degree of improvement of 13.8% in the warp and a degree of improvement of 14.8% in the bow of the wafer compared to the adjacent wafer control group. Accordingly, from the above experimental results, it may be known that if there is an etching pattern formed on the stress concentration place on one side of the silicon carbide wafer, it may help reduce the geometric warpage such as bow and/or warp in the appearance of the wafer.

### Experimental Example 2

In Experimental Example 2, a 6-inch silicon carbide wafer was used as the basis, and after the stress concentration place of the wafer was confirmed using an optical inspection machine, a circular etching pattern as shown in FIG. 1B to FIG. 1C was formed on the carbon side of the silicon carbide wafer such as the first surface 102A. After the etching pattern was formed, the silicon side of the wafer was roughly ground, but the carbon side was not ground (that is, the etching pattern of the carbon side was retained), and then a double-sided polishing was performed. After grinding and polishing, the bow and the warp of the wafer were measured. Same as the above experimental example 1, the previous wafer in the same wafer anchor was used as a control group, which had no etching pattern formed on the carbon side but was ground and polished on both sides. The experimental results are shown in Table 2:

TABLE 2

| | Warp | Bow |
|---|---|---|
| Control group | 249.72 | −268.89 |
| Experimental group | 56.19 | −51.02 |
| Degree of improvement | 77.5% | 81.0% |

As shown in Table 2, compared to the adjacent wafer control group, the wafer of the experimental group shows a degree of improvement of 77.5% in the warp and a degree of improvement of 81.0% in the bow of the wafer. Accordingly, from the above experimental results, it may be known that if there is an etching pattern formed on the stress concentration place on one side of the silicon carbide wafer, it may help reduce the geometric warpage such as bow and/or warp in the appearance of the wafer. In addition, if the carbon side having the etching pattern is not ground, it may greatly improve the geometric warpage such as bow and/or warp of the wafer.

### Experimental Example 3

In Experimental Example 3, a 6-inch silicon carbide wafer was used as the basis. In experimental group A, after a 4-inch circular etching pattern was formed on the carbon side of the 6-inch silicon carbide wafer, both sides were ground and polished. In experimental group B, after a 3-inch circular etching pattern was formed on the carbon side of the 6-inch silicon carbide wafer, both sides were ground and polished. In Experimental group C, after a 4-inch circular etching pattern was formed on the carbon side of the 6-inch silicon carbide wafer, the silicon side was ground before being polished. (the carbon side was not ground). After grinding and polishing, the bow and the warp of the wafer were measured. Same as the above-mentioned experimental example 1, the previous wafer in the same wafer anchor was used as control groups A-C, which had no etching pattern formed on the carbon side but was ground and polished on both sides. The experimental results are shown in Table 3:

TABLE 3

| | Warp | Bow |
|---|---|---|
| Control group A | 258.23 | −279.99 |
| Experimental group A | 222.72 | −238.51 |
| Degree of improvement A | 13.8% | 14.8% |
| Control group B | 253.38 | −274.77 |
| Experimental group B | 213.51 | −223.3 |
| Degree of improvement B | 15.7% | 18.7% |
| Control group C | 249.72 | −268.89 |
| Experimental group C | 56.19 | −51.02 |
| Degree of improvement C | 77.5% | 81.0% |

As shown in the experimental groups A-B in Table 3, it may be known that if there is an etching pattern formed at the stress concentration place on one side of the silicon carbide wafer, may help reduce the geometric warpage such as bow and/or warp in the appearance of the wafer. In addition, as shown in experimental group C, if the carbon side having the etching pattern is not ground, that is, if the etching pattern of the carbon side is retained, it may greatly improve the geometric warpage such as bow and/or warp of the wafer.

### Experimental Example 4

In experimental example 4, a 6-inch silicon carbide wafer was used as the basis. In experimental group D, an etching pattern transfer printed from the multiple linear striped openings 104-OP8 as shown in FIG. 3 was formed on the carbon side of the 6-inch silicon carbide wafer, but the etching pattern does not correspond to the stress concentration place of the wafer. In the experimental group E, an etching pattern transfer printed from the cross-shaped opening 104-OP7 as shown in FIG. 3 was formed on the carbon side of the 6-inch silicon carbide wafer, and was made to correspond to the stress concentration place of the wafer. In the experimental group F, an etching pattern transfer printed from the polygonal opening 104-OP6 shown in FIG. 3 was formed on the carbon side of the 6-inch silicon carbide wafer, and was made to correspond to the stress concentration place of the wafer. After the etching pattern was formed, the wafer is ground and polished on both sides, and the bow and the warp of the wafer were measured. Same as the above experimental example 1, the previous wafer in the same wafer anchor was used as control groups D-F, which had no etching pattern formed on the carbon side but was ground and polished on both sides. The experimental results are shown in Table 4:

TABLE 4

| | Warp | Bow |
|---|---|---|
| Control group D | 161.70 | −178.00 |
| Experimental group D | 217.40 | −235.74 |
| Degree of improvement D | No improvement | No improvement |
| Control group E | 176.92 | −191.08 |
| Experimental group E | 149.42 | −162.63 |
| Degree of improvement E | 15.5% | 14.9% |
| Control group F | 146.97 | −156.47 |
| Experimental group F | 102.06 | −107.86 |
| Degree of improvement F | 30.6% | 31.1% |

As shown in the experimental group D in Table 4, if the formed etching pattern does not correspond to the stress concentration place of the wafer, it may be unable to effectively reduce the geometric warpage such as bow and/or warp in the appearance of the wafer. In addition, as shown in the experimental groups E-F, if the formed etching pattern corresponds to the stress concentration place of the wafer, then no matter whether the etching pattern is formed in different shapes such as a cross shape or a polygonal shape, it may effectively improve the geometric warpage such as bow and/or warp in the appearance of the wafer. Among them, the degree of improvement of the polygonal etching pattern of the experimental group F is more favorable.

### Experimental Example 5

In Experimental Example 5, the bow/warp abnormal piece was used after fine polishing to further form an etching pattern transfer printed from the polygonal opening 104-OP6 as shown in FIG. 3 on the carbon side of the silicon carbide wafer. The experimental results are shown in Table 5:

TABLE 5

| | Warp before | Warp after | |
|---|---|---|---|
| | etching pattern | etching pattern | Degree of |
| | was formed | was formed | improvement |
| Abnormal piece 1 | 203.74 | 150.18 | 26.3% |
| Abnormal piece 2 | 223.56 | 215.09 | 3.8% |
| Abnormal piece 3 | 183.02 | 170.92 | 6.6% |
| Abnormal piece 4 | 49.617 | 42.82 | 13.7% |

As shown in the experimental results in Table 5, after further etching patterning is performed on the wafer surface the bow/warp abnormal piece used after fine polishing, the degree of warp of each wafer (abnormal pieces 1-4) has improved. Accordingly, the experimental results prove that the process of the disclosure may effectively reduce the gravity or the external force or adjust the influence of the internal stress on the geometric shape of the wafer.

To sum up, the surface of the wafer prepared in the embodiment of the disclosure has at least one etching pattern (or inward concave pattern) recessed inwards, or one convex pattern protruding outwards. After the wafer is ground or polished, it may reduce the gravity or the external force or to adjust the influence of the internal stress on the geometric shape of the wafer, so that the effect of reducing the geometric warpage such as bow and/or warp in the appearance of the wafer may be achieved.

What is claimed is:

1. A wafer processing method, comprising:
providing a wafer having a first surface and a second surface opposite to the first surface;
pasting a fixture pattern on the first surface to cover a first portion of the first surface, and exposing a second portion of the first surface by the fixture pattern;
performing a first etching step on the second portion of the first surface to form a first etching pattern on the first surface of the wafer; and
removing the fixture pattern from the first surface, and grinding the second surface of the wafer.

2. The method according to claim 1, wherein the second surface forms a convex pattern, and a position of the convex pattern corresponds to a position of the first etching pattern of the first surface after the second surface of the wafer is ground.

3. The method according to claim 2, wherein the convex pattern is one or more circles, ellipses, arcs, straight lines, rings, spirals, semicircles, polygons, irregular shapes, or a combination thereof protruding outwards from the second surface.

4. The method according to claim 1, wherein the first etching pattern is one or more circles, ellipses, arcs, straight lines, rings, spirals, semicircles, polygons, irregular shapes, or a combination thereof recessed inwards from the first surface.

5. The method according to claim 1, wherein the first etching pattern is a symmetrically disposed pattern.

6. The method according to claim 1, wherein the first etching pattern is an asymmetrically disposed pattern.

7. The method according to claim 1, wherein a ratio of an overall thickness of the wafer to an etching depth of the first etching pattern is 1:0.01 to 1:0.1.

8. The method according to claim 1, wherein an etching depth of the first etching pattern is 1 μm to 1000 μm.

9. The method according to claim 1, wherein an area of the first etching pattern occupies 25% to 85% of a total area of the first surface.

10. The method according to claim 1, wherein after removing the fixture pattern from the first surface and before grinding the second surface of the wafer, the method further comprises:
pasting a second fixture pattern on the first surface to cover a third portion of the first surface, and exposing a fourth portion of the first surface by the second fixture pattern;
performing a second etching step on the fourth portion of the first surface to form a second etching pattern on the first surface of the wafer; and
removing the second fixture pattern, and grinding the second surface of the wafer.

11. The method according to claim 10, wherein an etching depth of the second etching pattern is different from an etching depth of the first etching pattern.

12. The method according to claim 10, wherein an etching depth of the second etching pattern is the same as an etching depth of the first etching pattern.

13. The method according to claim 1, wherein a stress concentration place of the wafer is confirmed using an optical inspection machine, the stress concentration place of the wafer is exposed by the fixture pattern, and the first etching step comprises etching the stress concentration place of the wafer before the fixture pattern is pasted on the first surface.

14. The method according to claim 1, wherein the fixture pattern is pasted on the first surface using a wax or an adhesive tape.

15. A wafer, having a first surface and a second surface opposite to the first surface, wherein the first surface of the wafer has a first etching pattern recessed from the first surface.

16. The wafer according to claim 15, wherein the second surface has a convex pattern protruding outwards from the second surface, and a position of the convex pattern corresponds to a position of the first etching pattern of the first surface.

17. The wafer according to claim 15, wherein the first etching pattern comprises one or more circles, ellipses, arcs, straight lines, rings, spirals, semicircles, polygons, irregular shapes, or a combination thereof.

18. The wafer according to claim 15, wherein a ratio of an overall thickness of the wafer to an etching depth of the first etching pattern is 1:0.01 to 1:0.1.

19. The wafer according to claim 15, wherein an etching depth of the first etching pattern is 1 μm to 1000 μm.

20. The wafer according to claim 15, wherein an area of the first etching pattern occupies 25% to 85% of an total area of the first surface.

21. A wafer, having a first surface and a second surface opposite to the first surface, wherein the first surface of the wafer has a convex pattern protruding outwards from the first surface.

22. The wafer according to claim 21, wherein the second surface has an inward concave pattern recessed from the second surface, and a position of the inward concave pattern corresponds to a position of the convex pattern of the first surface.
